(19) United States
(12) Patent Application Publication
(10) Pub. No.: US 2002/0045036 A1
(43) Pub. Date: Apr. 18, 2002

(54) BGA SOLDER BALL SHEAR STRENGTH

(76) Inventors: ROBIN GORRELL, EAU CLAIRE, WI (US); WILLIAM PETEFISH, CHIPPEWA FALLS, WI (US); MIKE LEAF, EAU CLAIRE, WI (US); RANDY HASLOW, EAU CLAIRE, WI (US); BRANDON KHIEU, EAU CLAIRE, WI (US)

Correspondence Address: VICTOR M GENCO JR, W L GORE & ASSOCIATES INC, 551 PAPER MILL ROAD, PO BOX 9206, NEWARK, DE, 197149206

(21) Appl. No.: 09/334,083

(22) Filed: Jun. 16, 1999

(51) Int. Cl. B32B 15/00

(52) U.S. Cl. 428/209; 428/210

(57) ABSTRACT

The present invention relates to a process for eliminating low solder ball shear strength in electronic packages and interconnect substrates, and the resulting electronic package or interconnect substrates. In the present invention interconnect substrates are processed to provide a conductive surface contact with a layer of gold that forms a more substantial bond with a solder ball to increase the solder ball shear strength value, especially when the solder ball and corresponding conductive surface contact are electrically coupled to internal power and/or ground planes.

FIELD OF THE INVENTION

The present invention relates to a process for eliminating low solder ball shear strength in electronic packages and interconnect substrates, and the resulting electronic packages or interconnect substrates. Specifically, the present invention provides processes that enable treatment of a conductive contact surface with a layer of gold so that a more substantial bond with a solder ball is formed to increase the solder ball shear strength value, especially when the solder ball and corresponding conductive contact surface are electrically coupled to internal power and/or ground planes.

### BACKGROUND OF THE INVENTION

Present manufacturing protocols for electronic packages and interconnect substrates involve applying a nickel/gold deposit or layer over a conductive copper surface layer to provide improved performance characteristics. This nickel/gold deposit or layer is particularly useful for interconnects made with solder, as the nickel provides a diffusion barrier between the copper and the solder, and the gold serves to prevent the nickel surface from oxidizing, and thus maintains a wettable contact.

Although electroplating of nickel and gold has been typically used, deposition of the nickel-gold layers by electroless nickel followed by immersion gold has been gaining acceptance in the industry. An electroless nickel/immersion gold process offers the advantage of not requiring electrical contact for the deposition to take place, and is particularly well suited for very fine pitch flip chip ball grid array (BGA) devices. A typical process of electroless nickel-gold immersion is taught by Frederick A. Lowenheim, Electroplating, 1978, McGraw-Hill, pp. 389-409.

Although existing electroless nickel-gold immersion techniques offer many advantages over the prior electroplating techniques, sporadic solder joint failures by mechanical means have occurred. “A problem exists with electroless nickel/immersion gold (E.Ni/l.Au) board finishes on some pads, on some boards, that causes the solder joint to separate from the nickel surface, causing an open.” F. D. Bruce Houghton, ITRI Project on Electroless Nickel/immersion Gold Joint Cracking, IPC Printed Circuits Expo '99, Mar. 14-18,1999, S18-4(1-9).

Nicholas Biunno has determined that this problem originates in the immersion gold bath, and is caused by corrosion of the nickel surface while the contacts are being plated with gold. A Root Cause Failure Mechanism for Solder Joint Integrity of Electroless Nickel/Immersion Gold Surface Finishes, IPC Printed Circuits Expo '99, Mar. 14-18, 1999, S18-5(1-8). Further, Biunno has observed that not all pads on a given substrate are affected, and that the frequency of occurrence of the solder joint failures depends on what the particular pad is connected to in the substrate. Id.

The problems encountered as a result of prior art electroless nickel-gold immersion techniques have been overcome by the present invention disclosed hereinafter. In addition, the present inventors have also determined that the frequency of low BGA ball shear strengths is increased only for those pads connected to large internal power or ground planes at the time at which plating occurs.

### SUMMARY OF THE INVENTION

The present invention provides alternative procedures for eliminating the formation of low solder ball shear strength connections in electronics.

An object of the present invention is to provide solder ball shear strength values greater than 3800 grams/mm².

Another object of the present invention is selectively increasing solder ball shear strength values for solder balls connected to conductive surface contacts on an interconnect substrate which are electrically coupled to large internal power and/or ground planes.

An object of the present invention is providing a system for selectively increasing solder ball shear strength on conductive surfaces of an interconnect substrate by providing a rectifier having a negative lead, a positive lead, and a controller with the positive lead connected to an inert anode immersible in a gold immersion bath and a negative lead connectable to internal power and/or ground planes in said interconnect substrate. The rectifier is operated to apply sufficient voltage between the anode and the internal power and/or ground plane so that gold is deposited on conductive surfaces of an interconnect surface. Sufficient voltage is above that at which no current flows but below that which results in a poorly plated surface. The resulting gold layer forms a more substantial, shear resistant bond with a solder ball.

A further object of the present invention is to provide a process for selectively eliminating low solder ball shear values of solder balls.

A still further object of the present invention is to provide an interconnect substrate having electrically conductive contact surfaces electrically coupled to internal ground and/or power planes with solder balls affixed to those contact surfaces having a shear strength value of at least 3800 grams/mm².

Another object of the present invention is to provide a coating process which biases the large internal power and/or ground planes of an interconnect panel while gold is applied to a conductive surface on the panel to provide a surface coating that insures that low solder ball shear strength, when a solder ball is affixed to that conductive surface, is eliminated.

Another object of the present invention is to provide a coating process which minimizes or avoids the corrosion of a nickel surface during the gold immersion processing.

These and other objects and advantages will become more apparent when considered in conjunction with the following detailed description, non-limiting examples, drawings and appended claims.

### BRIEF DESCRIPTION OF THE DRAWINGS

FIG. 1 shows a panel of electronic substrates which include copper features or pads to be coated with nickel and gold.

FIG. 2 shows an isolated substrate obtained from the panel of FIG. 1 prior to the nickel-gold plating process.

FIG. 3 shows a system for performing the present invention.

FIG. 4 shows solder balls applied to a panel prepared in accordance with the present invention.

FIG. 5 provides solder ball strength shear data for solder balls connected to large planes, small planes and electrical traces of an interconnect substrate prepared in accordance with conventional electroless nickel-gold immersion coating techniques.

FIG. 6 shows comparative data of one embodiment in accordance with the present invention.

FIG. 7 shows a histogram of shear strength.

### DETAILED DESCRIPTION OF THE INVENTION

In the present invention interconnect substrates are processed to provide a conductive, surface contact with a layer of gold that forms a more substantial bond with a solder ball, that is more resistant to shear forces and that increases the solder ball shear strength value, especially when the solder ball and corresponding conductive surface contact are electrically coupled to internal power and/or ground planes

FIG. 1 shows an interconnect panel 1 containing several substrates 2 having exposed copper pads or other features 3 (e.g. conductive surface contacts) which are to be covered with nickel and gold in accordance with either prior art techniques or the process according to the present invention described hereinafter. The panel 1 includes a large internal (e.g., power and/or ground) plane 4, small internal planes 5 and traces 6.

The substrate of the panel may be formed from any suitable material such as inorganic or organic materials. Suitable inorganic materials include inorganic oxides and ceramics. Suitable organic polymers include but are not limited to polyolefins, e.g., polyethylene, polypropylene or fluoropolymers. Suitable fluoropolymers include porous polytetrafluoroethylene (PTFE), porous expanded polytetrafluoroethylene (ePTFE), porous copolymers of polytetrafluoroethylene and polyesters or polystyrenes, copolymers of tetrafluoroethylene and fluorinated ethylene-propylene (FEP) or perfluoroalkoxy -tetrafluoroethylene (PFA) with a C₁-C₄ alkoxy group. The substrate may contain organic or inorganic fillers, including polytetrafluoroethylene filled silica.

The large plane 4 covers an area of roughly 350 mm×350 mm, while the small plane covers an area roughly 40 mm×40 mm, at the time of plating. For this panel, the large internal plane is used for structural support for the entire panel, while the small internal plane covers only the area of an individual substrate.

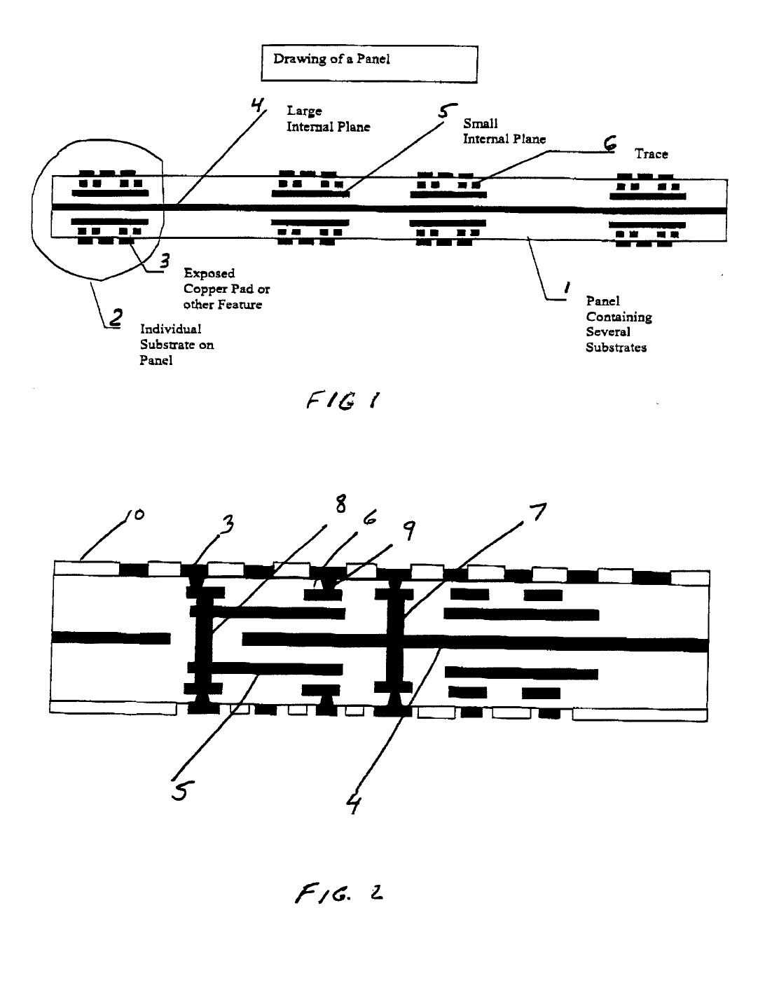

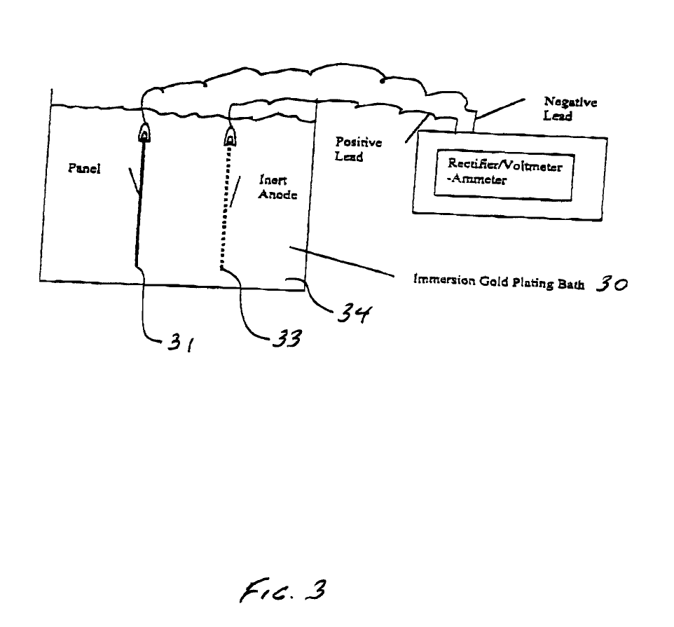

FIG. 2 is an enlarged view of a substrate 2 routed from panel 1, shown in FIG. 1, and shows the various electrical connections 7, 8 and 9 between exposed conductive contacts/features 3 and the large internal plane (4)/small plane (5)/ traces (6) in the substrate, and the solder mask 10 prior to deposition of the nickel-gold layers on contacts 3.

Prior to applying the nickel-gold layer to metal features of copper exposed on either or both outside surfaces of a panel of any size which contains multiple electronic interconnect substrates and is 350 mm×350 mm in size, in the present invention or in prior art processes, the panel is first immersed in a series of cleaning and microetch baths to clean and prepare the copper surfaces for the later deposition steps. The cleaning and microetch baths are followed by rinse baths, as are all the subsequent process steps.

The panel 1 is then immersed in a catalyst bath, typically an aqueous solution containing a palladium salt and an acid with the same anion as the palladium salt (i.e. palladium chloride and hydrochloric acid). The palladium deposits on and forms a film on the surface of the copper features 3. The panel is then immersed in an electroless nickel plating solution, typically an aqueous solution of nickel sulfate, sodium hypophosphite, sodium hydroxide, and proprietary stabilizers or grain refining compounds, and operated at temperatures near 85 degrees C. Nickel is deposited on the palladium catalyst and then continues to deposit on the nickel surface. Typical nickel deposits are 2-5 microns thick, but may be as thick as any application requires, including a deposit up to 50 microns thick.

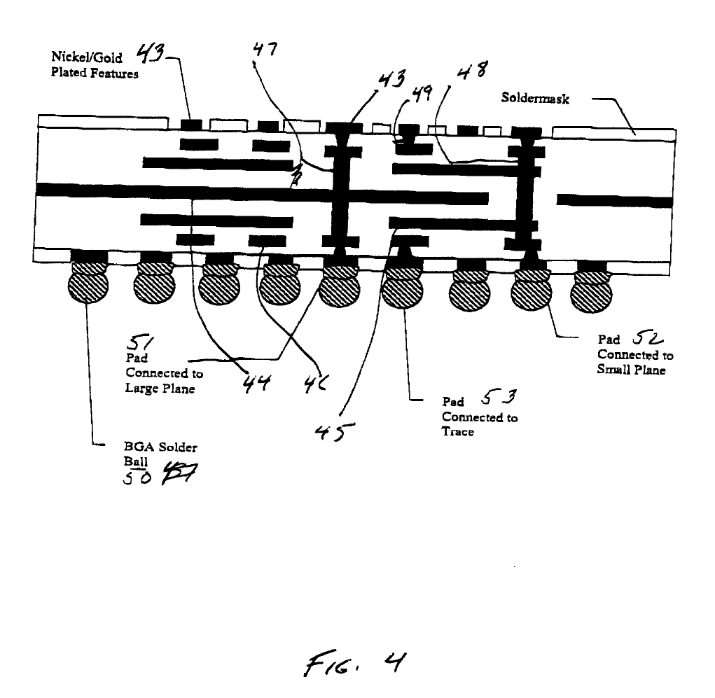

As shown in FIG. 3, a panel 31 is immersed in an immersion gold plating bath 30, but without the inert anode 33 of the present invention, which contains a gold plating solution 34. Typically the gold plating solutions 34 is an aqueous solution containing gold cyanide and a cyanide salt, such as potassium cyanide, and is operated at temperatures of 85 to 90 degrees C. The immersion gold bath may contain other salts or proprietary compounds. A thin layer of nickel at the surface of the exposed metal features goes into solution and is replaced by a very thin gold deposit, typically less than 0.2 microns. Solder balls are then applied using conventional techniques, such as those described below.

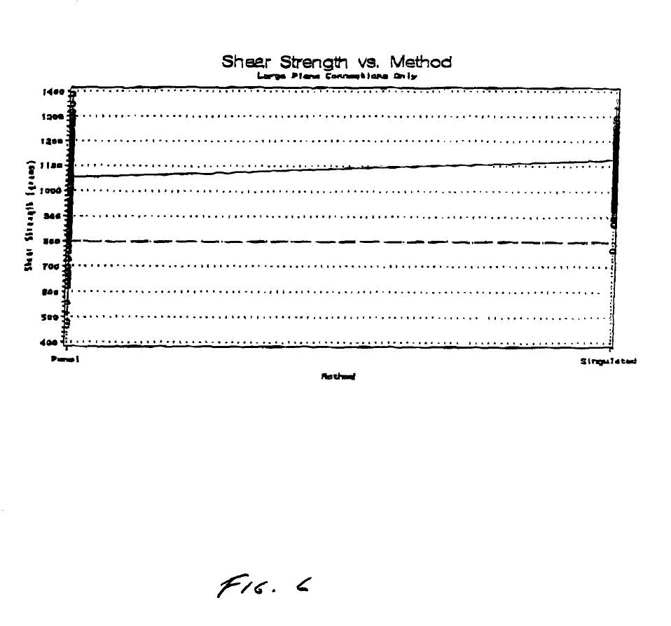

Ball shear strength in BGA's prepared in accordance prior art procedures, i.e., electroless nickel-gold immersion processing, without the use of the inert anode and biasing according to the present invention, has been evaluated. It has been determined that the frequency of low BGA ball shear strengths is increased only for those pads which are connected to large internal power planes or ground planes at the time at which plating occurs. The data from this evaluation is shown in FIG. 5, which shows ball shear strength values of pads connected to large internal planes, smaller internal planes, and to signal traces. In FIG. 5, the vertical reference line is typical of a desirable ball shear value for the pad diameter of 520 microns used in the substrate tested. As seen from FIG. 5, all the pads tested which were connected by solder balls to the small plane or to signal traces had a ball strength (shear strength) in excess of 800 grams. However, solder balls connected to pads connected to large planes have shear strength values below 800 grams, and including shear strength values between 400 and 500 grams.

One embodiment according to the present invention which eliminates low solder ball shear strength values below 3800 grams/mm² by routing the substrates from the panel prior to plating. Thereafter, the routed substrates are plated using conventional electroless nickel-gold immersion techniques. Routing reduces the size of the largest plane to which the pads are connected.

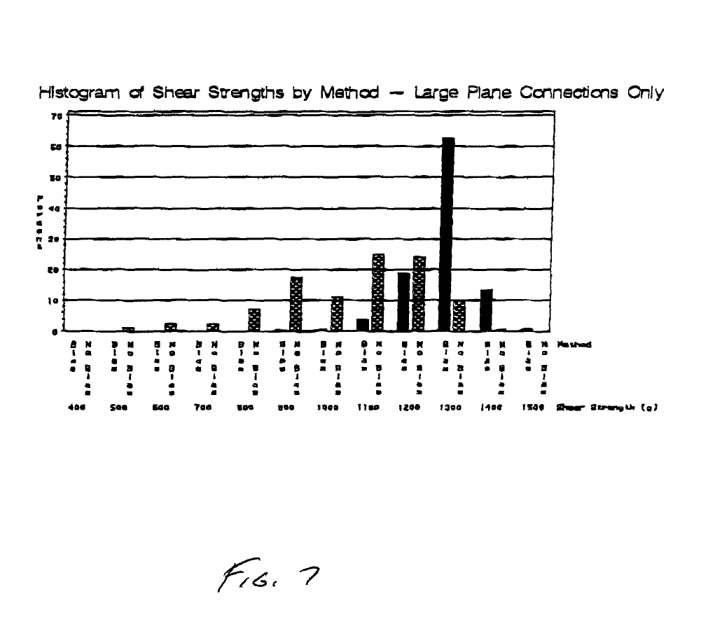

FIG. 6 shows comparative data from shear test evaluations made on solder balls that have been attached to nickel-gold coated feature pads on an entire panel in contrast to substrates that have been first routed from the panel (i.e., singulated) and then subjected to the nickel-gold plating process. In each case conventional electroless-nickel gold-immersion processing was used to plate the surface contacts with the nickel-gold layers. As can be seen from the data, using a singulated substrate instead of the entire panel results in the elimination of shear stress values below 800 grams (3800 grams/mm²).

An alternate embodiment of the present invention for eliminating low solder ball shear strength values is to apply a bias to the large internal plane in a panel relative to an inert electrode 33 submerged in the immersion gold plating bath while the panel is being plated. In contrast to prior art techniques, in the present invention, the process of applying the gold layer to the electroless deposited nickel layer is carried out in the presence of an inert anode preferably under biased conditions. As shown in FIG. 3, the 350-mm×350-mm substrate supporting panel 31 containing electroless coated nickel, is located in the immersion gold plating bath, and is plated with gold while connecting the large internal plane or planes of the panel 31 to the negative lead 35 of a rectifier 36, while the inert anode 37 is connected to the positive lead 38 of the rectifier 36.

A variety of materials may be used for the inert anode. In one embodiment the inert anode is a titanium mesh, which has been coated with platinum. When connections are made in this manner while the panel is being plated, and no voltage is applied to the rectifier 36, the ammeter of the rectifier will read a negative current flow. The rectifier is programmed to apply sufficient voltage which is above that voltage at which no current flows but below that voltage at which poor plating occurs.

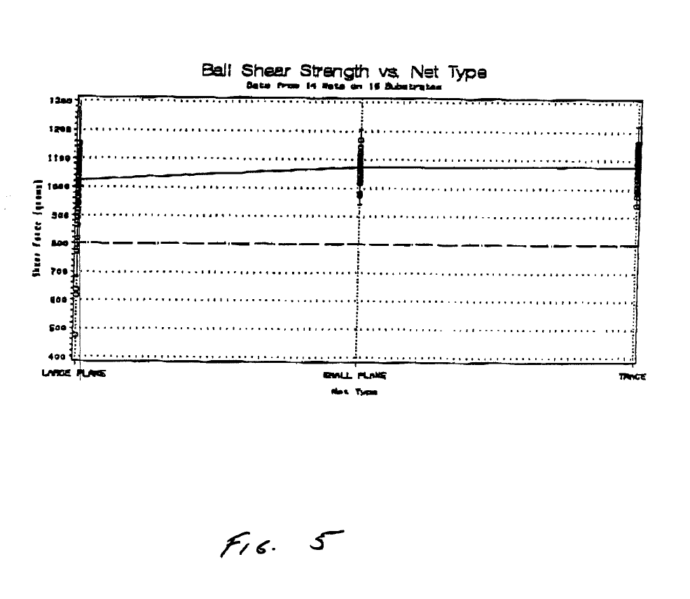

The panel 31 of FIG. 3 is shown as panel 41 in FIG. 4 and contains nickel-gold coated contacts/features 43, electrical connections 47, 48, 49 respectively electrically connecting features 43 with large plane 44, small plane 45 and traces 46. BGA solder balls 50 are connected to pad features 51, 52 and 53, which have the nickel-gold coating applied according to the present invention.

Prior to attaching the solder balls the nickel-coated plated contact features prepared in accordance with the present invention, the substrate is preconditioned. The substrate is first heated to a temperature of about 125+/−10 degrees C. for 240+/−10 minutes in an oxygen containing environment, e.g., air. Next the substrate is heated at a temperature of about 150+/−10 degrees C. for approximately 120+/−10 minutes in a similar atmosphere. The third step involves a repetitive heat treatment (reflow) where the substrate is heated at a temperature between 150 degrees C and 170 degrees C. for 90 seconds or longer and then heated to 180 degrees C or higher for about 60 to 90 seconds. Peak temperature should not exceed 220+/−5 degrees C. This dual stage heat treatment symbolizes solder reflow conditions and should be repeated twice.

Solder balls are now attached to the substrate as seen in FIG. 4. The solder balls are formed from an eutectic materials approximately 0.6 mm in diameter. Suitable solder materials include Pb/Sn compositions, such as those taught in Electronic Packaging and Interconnection Handbook, Charles A. Harper Ed. in Chief, 2nd edition, 1997, McGraw-Hill: Chapter 5: Solder Technologies for Electronic Packaging, pp. 5.4-5.6, Jennie S. Hwang. In one embodiment of the present invention the solder balls are a eutectic mixture of 63% Sn, 37% Pb. The flux, such as Rosin flux (RMA type), or other suitable flux materials, such as water soluble or no clean flux, is applied to the nickel-gold covered contact pads. Then the solder balls are placed on the substrate and reflowed following the reflow heat treatment discussed above. That is, once the solder ball are positioned in place, the substrate, flux and solder balls are heated at a temperature between 150 degrees C. and 170 degrees C. for 90 seconds or longer and then heated to 180 degrees C. or higher for about 60 to 90 seconds. Peak temperature should not exceed 220+/−5 degrees C. The assembly is then placed in a heater block or oven with the BGA ball side up whereby the entire assembly remains for 100 to 120 seconds, keeping the temperature of the BGA ball side at 215±5 degrees C., and then let it cool until it becomes room temperature.

The shear strength of the solder balls on the assembly which has had the gold layer applied in accordance with the present invention is then tested. Clearance between the solder mask around the ball to be measured and the measurement head should be about 50 to 100 microns. Shear is applied to the solder balls at 100 microns/sec using a ball shear test device such as the Dage Model BT2400 Bond Testing System with an LC5KG 5 kg load cell. After the shear strength measurement, each pad is visually inspected and classified into the following categories of solder ball breakage mode. Shears which result in a large portion of the pad being exposed are considered poor as pads which exhibit this failure mode during testing are likely to fail in use when the substrate is subjected to bending. Grades are often given to characterize the failure modes.

| Breakage | Area ratio of the solder staying on the |
|---|---|
| mode | pads |
| A | 100% |
| B | 75% to 99% |
| C | 50% to 74% |
| D | Less than 50% |

wherein:

A=100% solder remaining on the pads (shear is completely in solder ball).

B=75 to 99% solder remaining on the pads.

C=50 to 74% solder remaining on the pads.

D=Less than 50% solder remaining on the pads.

Those with even one solder ball falling under Mode D are considered unacceptable.

FIG. 7 is a histogram of ball shear values for panels plated without bias applied and panels plated with a 1.1 Volt bias applied.

In addition to improved ball shear strength, the mode in which the solder ball shears is also important.

The following table compares the failure modes from panels plated with and without bias in accordance with the present invention:

| | Bias | | No Bias | | |
|---|---|---|---|---|---|
| Grade | Frequency | Pct | Frequency | Pct | Freq. Total |
| A | 254 | 86.39 | 7 | 3.72 | 261 |
| B | 38 | 12.83 | 45 | 23.94 | 83 |
| C | 2 | 0.68 | 32 | 17.02 | 34 |
| D | 0 | 0.00 | 104 | 55.32 | 104 |
| Total | 294 | | 188 | | 482 |

As can be seen, 55% of the shears occurring on the panels plated without bias are the poor D mode failures, while no D mode failures occur in the panels plated with bias.

While the invention has been disclosed in preferred embodiments, various modifications may be made therein by those skilled in the art without departing from the spirit and scope of the invention, as defined in the appended claims.

1. An interconnect substrate comprising:
a substrate having electrically conductive contact surfaces electrically connected to large power or ground planes and solder balls affixed to said contacts surfaces, said affixed solder balls having a shear strength value of at least 3800 grams/mm².

2. The interconnect substrate according to claim 1 wherein said substrate comprises an inorganic material.

3. The interconnect substrate according to claim 2 wherein said inorganic material is a ceramic.

4. The interconnect substrate according to claim 1 wherein said substrate comprises an organic material.

5. The interconnect substrate according to claim 4 wherein said organic material comprises a fluoropolymer.

6. The interconnect substrate according to claim 5 wherein the fluoropolymer is a polytetrafluoroethylene polymer.

7. The interconnect substrate according to claim 5 wherein the fluoropolymer is expanded a polytetrafluoroethylene polymer.

8. The interconnect substrate according to claim 7 wherein the expanded polymer further includes and inorganic or organic filler.

9. The interconnect substrate according to claim 1 wherein said solder shear strength is at least 800 grams.

10. The substrate according to claim 1 wherein said conductive contact surfaces include a base layer of copper.

11. The substrate according to claim 10 wherein said copper base layer includes an outer layer of electroless nickel.

12. The substrate according to claim 1 wherein the conductive contact surfaces include a layer of nickel 2 to 5 microns in thickness.

13. The substrate according to claim 1 wherein the conductive contact surfaces include an outer layer of gold.

14. The substrate according to claim 13 wherein the layer of gold is applied in a gold immersion bath operated in the presence of an inert anode.

15. The substrate according to claim 12 wherein the nickel layer includes an outer layer of gold.

16. The substrate according to claim 14 wherein the layer of gold is applied to the nickel layer in a gold immersion bath while the ground or power plane is biased relative to an inert electrode in the immersion bath.

17. A system for selectively increasing solder ball shear strength on conductive surfaces of an interconnect substrate comprising:
(a) a rectifier having a negative lead, a positive lead, and a controller; and
(b) an inert anode immersible in a gold immersion bath and having one end electrically coupled to said positive lead, wherein said negative lead is connectable to internal power and/or ground planes, and said controller programs said rectifier to bias said power and/or ground planes relative to said anode so that gold is deposited on conductive surfaces of an interconnect surface.

18. The system according to claim 17, wherein the controller programs the rectifier to apply approximately 1.1 volts.

19. The system according to claim 14, wherein the controller programs the rectifier to apply sufficient voltage above that voltage at which no current flows between the panel and the inert electrode.

20. A process for selectively increasing solder ball shear strength values comprising:
(a) providing a panel having a power and/or ground plane of a preselected size, said panel having at least one conductive surface contact electrically coupled to said power and/or ground plane;
(b) reducing said preselected size of said power and/or ground plane of said panel;
(c) sequentially applying electroless nickel and immersion gold to said at least one surface contact; and
(d) attaching a solder ball to said at least one surface contacts of step (c).

21. A process for selectively increasing solder ball shear strength values comprising:
(a) immersing a panel having power and/or ground planes and at least one conductive nickel surface contact in a gold immersion bath;
(b) concurrently biasing said panel relative to an inert anode located in said bath during deposition of gold over said nickel surface to form at least one conductive nickel-gold conductive surface contact; and
(c) attaching solder balls to said at least one conductive surface contact of step (b).

22. The process according to claim 21, wherein the panel is connected to a negative lead of a rectifier which is operated to apply at least 1.1 volts.

23. The process according to claim 21, wherein the rectifier is operated to apply sufficient voltage above that at which no current flows between the panel and the inert electrode but less than that voltage which results in a poor plating surface
